(19) United States
(12) Patent Application Publication
(10) Pub. No.: US 2003/0029716 A1
(43) Pub. Date: Feb. 13, 2003

(54) DWDM filter system design

(76) Inventor: Ga-Lane Chen, Fremont, CA (US)

Correspondence Address: WEI TE CHUNG, FOXCONN INTERNATIONAL, INC., 1650 MEMOREX DRIVE, SANTA CLARA, CA, 95050, US

(21) Appl. No.: 09/929,626

(22) Filed: Aug. 13, 2001

(51) Int. Cl. G02F 1/00; C23C 14/32

(52) U.S. Cl. 204/192.11; 204/298.04; 359/237

(57) ABSTRACT

This invention provides a new DWDM filter deposition system, which uses quarter wavelength antenna and electron cyclotron resonance magnets to enhance the plasma density to improve the quality of DWDM filter.

### BACKGROUND OF THE INVENTION

1. Field of the Invention

The present invention relates to a new DWDM system design, which uses microwave source with over 2.45 GHz frequency to produce super high density plasma (5×10¹⁰ cm⁻³ to 9×10¹² cm⁻³) for thin film deposition for DWDM filter which shows higher adhesion, mechanical, and optical properties. The automatic microwave tuning by using antenna theory is very reliable and do not have the disadvantage of replacing filament or grids.

2. The Prior Art

Conventional DWDM filter consists multilayer thick films on glass substrates. The filter was fabricated by the e-beam evaporation with plasma source or Kaufman source, ion-beam deposition (IBD), and ion-beam assisted deposition (IBAD).

For e-beam evaporation with plasma or Kaufman source, the plasma is generated by hot filament electron emission. The Plasma can be confined by the multi-pole magnetic field. The density of plasma is in the range of 1×10⁹ to 9×10¹⁰ cm⁻³. The cathode materials (La B₆) filament needs to be replaced per 70 hours. The graphite heater has to be heated to 1500° C. to generate thermal ionic electron. The heater needs to be replaced per 200 hours. The plasma can be polluted by filament materials.

The convention ion beam deposition (IBD) or ion beam assisted deposition (IBAD) has high frequency (HF) or radio frequency (RF) source to ignite plasma. The high frequency plasma is in the range of 40000 to 400000 Hz. RF plasma has frequency of 13.56 MHz, or 27.12 MHz. The plasma is excited by high voltage with low current RF power with plasma confined by the multipole magnetic field. The plasma density is in the range of 1×10⁹ to 9×10¹⁰ cm⁻³. Due to RF coupling and high plasma potential, the grid in the ion source have to be cleaned after 100 hours usage.

U.S. Pat. No. 5,962,080 utilizes two ion beams to deposit insulating thin films on a substrate. The first ion beam preferably of inert gas is than directed toward the target to disperse the target material. Simultaneously, the second ion beam which includes another constituent element of the insulating thin film is also directed toward the substrate. The material from the target and the element of the second ion beam react in proper stoichiometry and is deposited onto the substrate as the insulating thin film.

U.S. Pat. No. 5,589,042 disclosures that an ion beam sputter etching system is used to etch a uniform reflective layer that was previously deposited on a transparent substrate to fabricate optical ramp filters.

U.S. Pat. No. 5,192,393 describes a method of growing thin film on a substrate. In this method, a gas substance is excited to be ions. These ions are neutralized by electrons. The neutral particles are guided into the substrate to form thin film.

U.S. Pat. No. 4,811,690 disclosures a thin film deposition apparatus which comprises of a vacuum chamber, a vapor generating source, an accelerating electrode. The cluster ion beam method uses an ionizing filament for emitting thermoelectrons to ionize the clusters from a vapor generating source.

U.S. Pat. No. 4,676,194 disclosures a method for forming a thin film on a substrate. This method comprises aligning an evaporation means for an evaporating material to be deposited on the substrate, a plasma generating zone for dissociating an ion-forming gas into ions and electrons, an ion accelerating zone for accelerating the resulting ions and irradiating them onto the substrate, and said substrate on a substantially straight line in the order stated, and depositing a vapor of the evaporating material on the substrate through the plasma generating zone and the ion beam accelerating zone.

U.S. Pat. No. 4,424,103 disclosures a method and apparatus for thin film deposition. It comprises bombarding a target obliquely in a vacuum chamber with a linear ion gun. The linear ion gun generates an ion beam which impacts the target over an area having a width substantially greater than a height. Target material in the impacted area is sputtered. The sputtered target material is deposited onto a surface by translating the surface at a controlled rate through the sputtered material.

### SUMMARY OF THE INVENTION

The conventional methods for fabricating thin film filter include ion beam deposition, ion beam assisted deposition, electron beam evaporation with plasma source or Kaufman source, etc. There are several disadvantages of these processes such as the lifetimes of cathode materials filament, grid and graphite heater. These processes also produce environment pollution during the fabrication.

Due to the disadvantages of conventional methods, a novel microwave design is applied to the DWDM filter fabrication. This new system has generated plasma by microwave and the density of plasma is in the range of 5×10¹⁰ cm⁻³ to 9×10¹² cm⁻³ with frequency at 2.45 GHz or higher.

This design can be used for WDM and CWDM with wavelength 1300 to 1620 nm, edge filter, long pass band filter, and gain flattening filter, too. It can be used for C band, L band, and other optical coating.

### BRIEF DESCRIPTION OF THE DRAWINGS

FIG. 1 is the DWDM filter design with four cavity layers and the structure of the first layer.

FIG. 2 is the structure of the second cavity layer.

FIG. 3 is the structure of the third cavity layer.

FIG. 4 is the structure of the fourth cavity layer.

FIG. 5 is the new design of vacuum deposition system with new microwave source of the multiple layers coating for DWDM filter.

### DETAIL DESCRIPTION OF THE PREFERRED EMBODIMENT

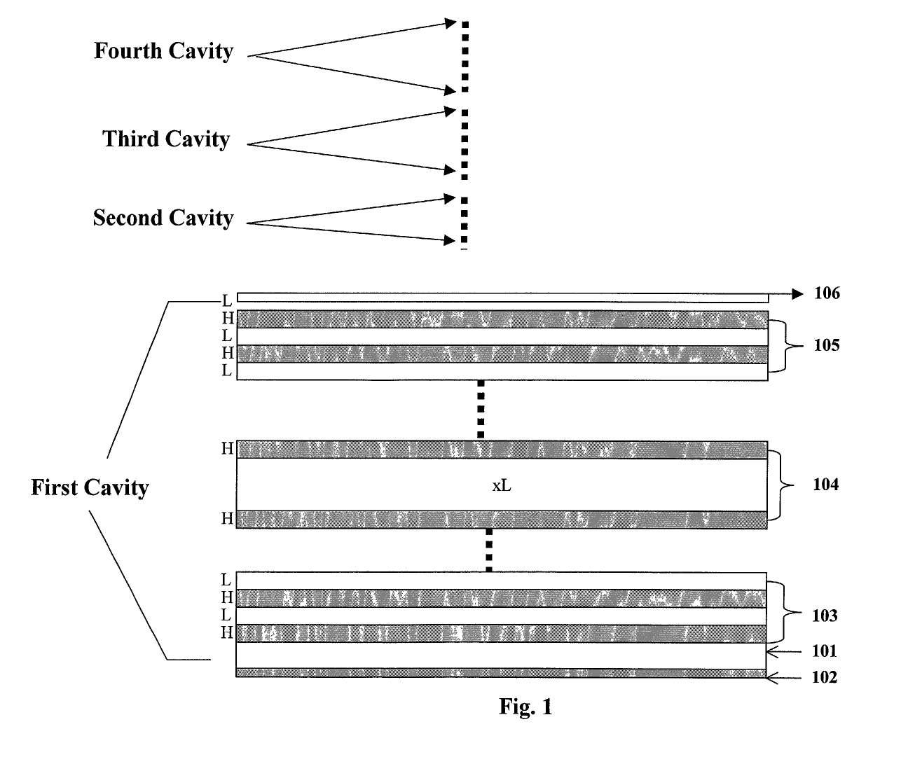

Referring to FIG. 1, the four-cavity film stack was deposited on the glass substrate 101. Each cavity consists optical mirror layers and a spacer layer. The symbol H represents high reflective index layer with thickness equal to ¼ of wavelength. The material of the high reflective index layer could be Ta₂O₅ or Nb₂O₃. The symbol L represents low reflective index layer with thickness equal to ¼ of wavelength. The material of the low reflective index layer could be SiO₂ or Al₂O₃. There is an antireflective (AR) coating layer 102 on the back of glass substrate, which is to enhance the light transmittance and reduces the insertion loss of DWDM device.

The design of multiple layers of the first cavity is (HL)^{m}H(xL)H(LH)^{m}L, where m is integer number and in the range of 2, 3, 4, 5, 6, 7, 8, 9, 10, 11, and 12. The first optical mirror layer 103 of the first cavity is (HL)m. The spacer layer 104 is H(xL)H, where x is an even number such as 2, 4, 6, 8, and 10. The second optical mirror layer 105 of the first cavity is (LH)^{m}. The last layer L 106 is the coupling layer between the first cavity and the second cavity.

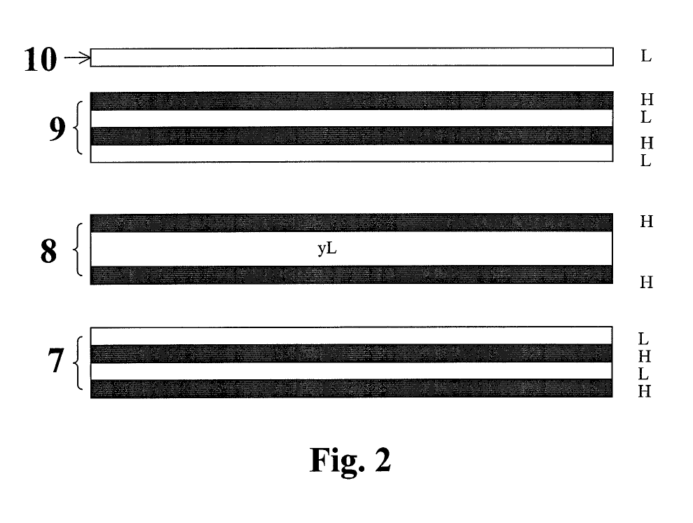

Referring to FIG. 2, the design of multiple layers of the second cavity is (HL)^{m+1}H(yL)H(LH)ⁿ⁺¹L, where m and n are integer number and in the range of 2, 3, 4, 5, 6, 7, 8, 9, 10, 11, and 12. The first optical mirror layer 201 of the second cavity is (HL)^{m+1}. The spacer layer 202 is H(yL)H, where y is an even number such as 2, 4, 6, 8, 10. The second optical mirror layer 203 of the second cavity is (LH)ⁿ⁺¹. The last layer L 204 is a coupling layer between the second cavity and the third cavity.

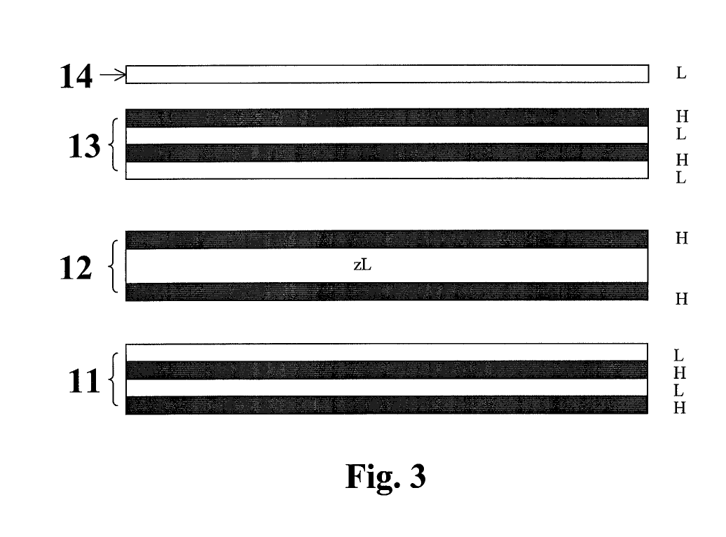

Referring to FIG. 3, the design of multiple layers of the third cavity is (HL)^{m+1}H(zL)H(LH)ⁿ⁺¹L, where m and n are integer number and in the range of 2, 3, 4, 5, 6, 7, 8, 9, 10, 11, and 12. The first optical mirror layer 301 of the third cavity is (HL)^{m+1}. The spacer layer 302 is H(zL)H, where z is an even number such as 2, 4, 6, 8, 10. The second optical mirror layer303 of the third cavity is (LH)ⁿ⁺¹. The last layer L 304 is a coupling layer between the third cavity and the fourth cavity.

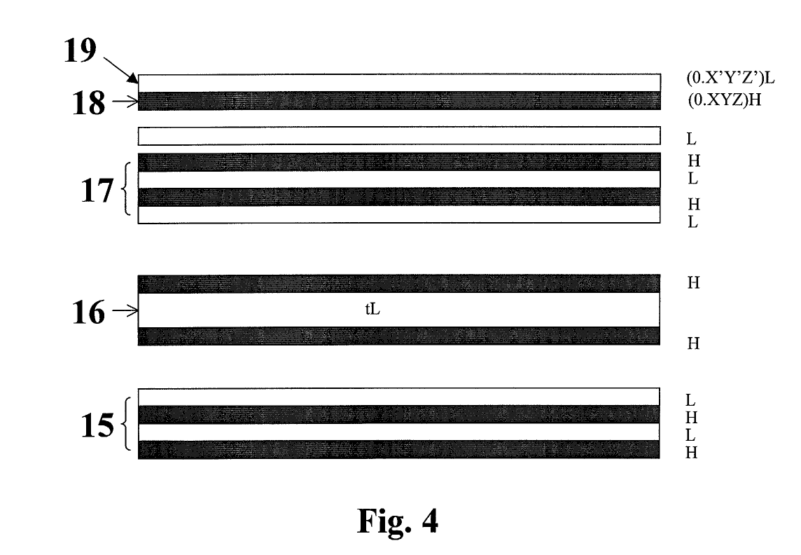

Referring to FIG. 4, the design of multiple layers of the fourth cavity is (HL)^{m}H(tL)H(LH)^{m-1}L+0.XYZH+0.X′Y′Z′L, where m is the integer number and in the range of 2, 3, 4, 5, 6, 7, 8, 9, 10, 11, and 12. The first optical mirror layer 401 of the fourth cavity is (HL)^{m}. The spacer layer 402 is H(tL)H, where t is an even number such as 2, 4, 6, 8, 10. The second optical mirror layer 403 of the fourth cavity is (LH)^{m-1}. The last two layers (0.XYZ)H 404 and (0.X′Y′Z′)L 405 are used to optimize the transmittance of film stacks of these four cavity design.

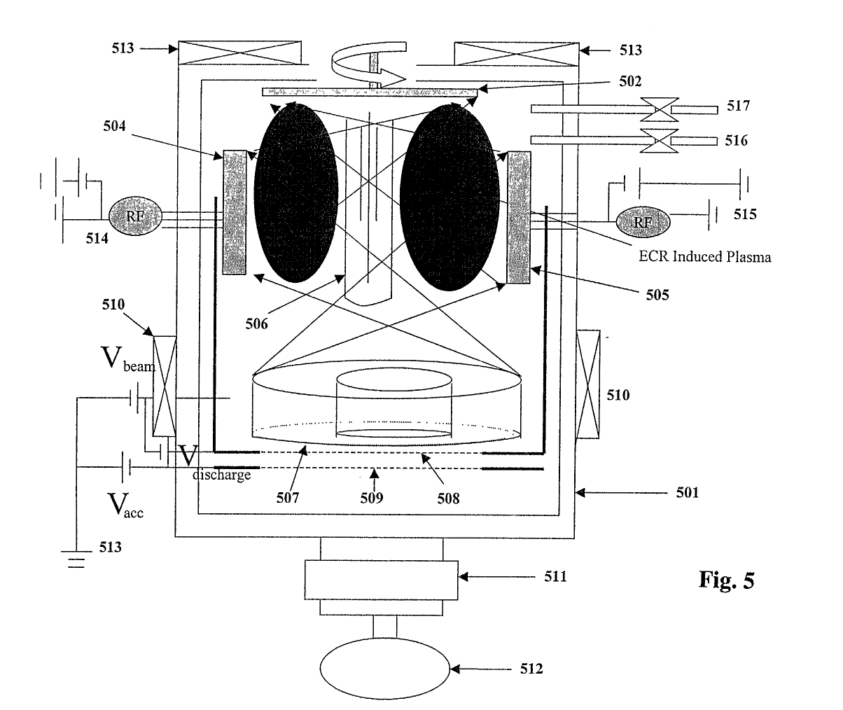

Referring to FIG. 5, the new design of vacuum deposition system with new microwave source of the multiple layers coating for DWDM filter comprises a vacuum chamber 501, a rotating substrate 502, ECR magnets 503, SiO₂ target 504, Ta₂O₅ target 505, a quarter wavelength antenna 506, an anode 507, a screen grid 508, an accelerator grid 509, permanent magnet 510, a high vacuum pump 511, a mechanical pump 512, a power supply 513 for the anode 507, the screen grid 508, and the accelerator grid 509, a power supply 514 for the SiO₂ target 504, a power supply 515 for the Ta₂O₅ target 505, a gas flow controller 516 for oxygen, a gas flow controller 517 for inert gas.

The thin film process must be run under the vacuum condition in the vacuum chamber 501. The mechanical pump 512 connected to the high vacuum pump 511 is used to reduce the gas density to the 10⁻³/cm³ in the vacuum chamber 501. The high vacuum pump 511 connected to the vacuum chamber 501 is to reduce the gas density in the vacuum chamber to 10⁻⁷/cm³. The gas flow controller for oxygen 516 and the gas flow controller for inert gas 517 are connected to the vacuum chamber 501 to keep the densities of oxygen and inert gas such as argon in the vacuum chamber 501.

The power supply provides electricity to the accelerator grid509, the screen grid 508, and the anode 507 to produce stability ion source to bombard SiO₂ target 504 and Ta₂O₅ target 505. The permanent magnet 510 is used to stabilities the ion density. The power supply 514 provides electricity for the SiO₂ target 504. The power supply 515 provides electricity for the Ta₂O₅ target. The SiO₂ target 504 and Ta₂O₅ target 505 are bombarded by ion beam to form plasma, which is formed with the thin film on the rotating substrate 502. The quarter wavelength antenna 506 and the ECR magnets 503 are used to improve the density of plasma to get higher density thin film on the substrate 502.

We claim

1. A new DWDM deposition system comprising:
a chamber;
a target disposed in the chamber;
a stable ion source bombarding the target;
a quarter wavelength antenna spatially disposed beside the target;
an electron cyclotron resonance (ECR) region formed between said target and said antenna; and
an automatic microwave tuning being done by said antenna for achieving high density plasma; and
a rotatable substrate positioned above the ECR region so as to form plasmas thereon.

2. The system as defined in claim 1, wherein magnet device is used to stabilize an ion density.

3. The system as defined in claim 1, wherein a density range is from 5×10¹⁰ cm⁻³ to 9×10¹² cm⁻³ with frequency at 2.45 GHz or higher.

4. A DWDM filter design comprising first, second, third and fourth cavities each consisting of optical mirror and spacer layers wherein L represents a low reflective index layer with thickness equal to one fourth of a wavelength and H represents a high reflective index layer with thickness equal to one fourth of the wavelength, a first cavity being (HL)^{m}H(xL)H(LH)^{m}L, wherein m is integer number and in the range of 2, 3, 4, 5, 6, 7, 8, 9, 10, 11, and 12, a first optical mirror layer of the first cavity being (HL)m, a spacer layer being H(xL)H, wherein x is an even number such as 2, 4, 6, 8, and 10, a second optical mirror layer of the first cavity is (LH)^{m}, a layer L being a coupling layer between the first cavity and the second cavity.

5. The filter design as defined in claim 4, a second cavity is defined with (HL)^{m+1}H(yL)H(LH)ⁿ⁺¹L, wherein m and n are integer number and in the range of 2, 3, 4, 5, 6, 7, 8, 9, 10, 11, and 12, a first optical mirror layer of the second cavity being (HL)^{m+1}, a spacer layer being H(yL)H, wherein y is an even number such as 2, 4, 6, 8, 10, a second optical mirror layer of the second cavity being (LH)ⁿ⁺¹, L being a coupling layer between the second cavity and the third cavity.

6. The filter design as defined in claim 5, wherein a third cavity is defined with (HL)^{m+1}H(zL)H(LH)ⁿ⁺¹L, wherein m and n are integer number and in the range of 2, 3, 4, 5, 6, 7, 8, 9, 10, 11, and 12, a first optical mirror layer of the third cavity being (HL)^{m+1}, a spacer layer being H(zL)H, wherein z is an even number such as 2, 4, 6, 8, 10, a second optical mirror layer of the third cavity being (LH)ⁿ⁺¹, a last layer L being a coupling layer between the third cavity and the fourth cavity.

7. The filter design as defined in claim 6, wherein a fourth cavity is (HL)^{m}H(tL)H(LH)^{m-1}L+0.XYZH+0.X′Y′Z′L, wherein m is the integer number and in the range of 2, 3, 4, 5, 6, 7, 8, 9, 10, 11, and 12, a first optical mirror layer of the fourth cavity is (HL)^{m}, the spacer layer being H(tL)H, wherein t is an even number such as 2, 4, 6, 8, 10, a second optical mirror layer of the fourth cavity being (LH)^{m-1}, last two layers (0.XYZ)H and (0.X′Y′Z′)L being used to optimize the transmittance of film stacks of these four cavity design.

8. A method of making a DWDM filter device, comprising the steps of:
providing a chamber;
providing a stable ion source around a bottom portion of the chamber to generate an ion beam;
providing a target adapted to be bombarded by said ion beam;
providing an antenna opposite to said target and defining an ECR (electron cyclotron resonance) region;
an automatic microwave tuning by using antenna theory to achieve super high density plasma corresponding to the ion beam; and
disposing a rotatable substrate above said ECR region for obtaining multi-layer coating.

9. The method as defined in claim 8, wherein said antenna is of a quarter wavelength.
